(19) United States
(12) Patent Application Publication
(10) Pub. No.: US 2009/0027822 A1
(43) Pub. Date: Jan. 29, 2009

(54) Transient blocking unit having a fab-adjustable threshold current

(76) Inventors: Mohamed N. Darwish, Campbell, CA (US); Tao Wei, San Jose, CA (US); Stephen Coates, San Francisco, CA (US); Richard A. Harris, Karana Downs (AU); Andrew J. Morrish, Saratoga, CA (US)

Correspondence Address: LUMEN PATENT FIRM, 2345 YALE STREET, SECOND FLOOR, PALO ALTO, CA, 94306, US

(21) Appl. No.: 12/220,798

(22) Filed: Jul. 25, 2008

Related U.S. Application Data
(60) Provisional application No. 60/962,221, filed on Jul. 26, 2007.

(51) Int. Cl. H02H 3/22; H01L 21/8234

(52) U.S. Cl. 361/111; 438/238; 257/E21.616

(57) ABSTRACT

A transient blocking unit (TBU) is a transistor circuit that is normally on, but rapidly and automatically switches to a high-resistance current blocking state when a current threshold is exceeded, thereby protecting a series connected load from over-voltage or over-current conditions. Process variation of transistor threshold voltage and on-resistance can cause undesirable variation of the TBU threshold current and/or of TBU resistance. Control of TBU threshold current and/or resistance is improved by providing for trimming the TBU during its fabrication to provide a one-time adjustment of the threshold current or resistance. Such trimming can be done with a resistive trimming circuit placed in series with the on-resistance of the relevant TBU transistor. Alternatively, a segmented TBU transistor having an on-resistance that is adjustable by way of wire bonding during fabrication can be employed.

### CROSS REFERENCE TO RELATED APPLICATIONS

This application claims the benefit of U.S. provisional patent application 60/962,221, filed on Jul. 26, 2007, entitled “Programmable Control IC for Circuit Protection”, and hereby incorporated by reference in its entirety.

### FIELD OF THE INVENTION

This invention relates to suppression of electrical transients.

### BACKGROUND

A transient blocking unit (TBU) is an arrangement of transistors connected such that the TBU resistance is ordinarily low, but this resistance automatically and rapidly switches to a high value in response to an over-current condition. Due to this characteristic behavior, TBUs are applicable for protecting series connected loads from over-current or over-voltage conditions.

FIG. 1 shows a typical example of a TBU. In this example, Q1 and Q2 are both depletion mode transistors (i.e., normally on). As I_{TBU} increases, passage of I_{TBU} through the series resistance of Q1 and Q2 provides gate voltages at Q1 and Q2 that tend to switch the circuit off. Below a well-defined current threshold, this tendency is negligible, and the series resistance of the TBU is low. Above this current threshold, positive feedback sets in, because gate voltages tend to increase as the transistors start to switch off. As a result, the TBU rapidly switches to a high-resistance current blocking state, thereby protecting its series-connected load. The example of FIG. 1 is referred to as a uni-directional TBU because the device works as described above for one polarity of I_{TBU}, but not for the other polarity of I_{TBU}.

FIG. 2 shows a typical example of a bi-directional TBU. This example can be understood as effectively being two uni-directional TBUs in series. More specifically, Q1 and Q2 of FIG. 2 form the uni-directional TBU of FIG. 1, while Q1 and Q3 of FIG. 2 form a second uni-directional TBU having opposite polarity. In this manner, protection can be provided for transients of either polarity. More specifically, the combination of Q1 and Q2 defines a first current threshold T1, and the combination of Q1 and Q3 defines a second current threshold T2, where T1 and T2 have opposite signs. U.S. Pat. No. 5,742,463 provides further description of uni-directional and bi-directional transient blocking units. Refinements of the basic TBU concept have also been considered in the art. For example, US 2006/0098363 describes a TBU approach where a core TBU is combined with a discrete high-voltage device.

### SUMMARY

As indicated above, the threshold current of a TBU depends on the series resistance of the depletion mode transistors when they are in a conducting state. This parameter is frequently referred to as the transistor on-resistance. For most applications, it is desirable to minimize the on-resistance, e.g., as considered in U.S. Pat. No. 5,869,865. However, the TBU application is unusual, since the basic TBU circuit would not function with transistors having zero on-resistance. Instead, for TBU fabrication, it is highly desirable that on-resistance be a well-controlled device parameter.

However, it turns out in practice that device on-resistance is typically a relatively poorly controlled device parameter, and that this lack of control of device on-resistance has significant effects on TBU yield. TBUs having a threshold current that does not meet product specifications (e.g., 150 mA +/−20%) are rejected, thereby decreasing yield. Device on-resistance variation is a significant contributor to this yield issue.

In practice, transistor threshold voltage variation is also an important contributor to TBU current threshold variation. In such cases, it is important to provide a match of on-resistance to threshold voltage to make TBU threshold current more consistent. For example, the TBU threshold current of the bi-directional TBU of FIG. 2 is often roughly given by Vₜ₂/Rₒₙ₁ or Vₜ₃/Rₒₙ₁, where Vₜ₂ and Vₜ₃ are the threshold voltages of Q2 and Q3 respectively, and Rₒₙ₁ is the on-resistance of Q1. Threshold voltages Vₜ₂ and Vₜ₃ can also vary significantly as a result of normal process variation. In such situations, it is important to match the on-resistance of Q1 to the measured value of Vₜ₂ (or Vₜ₃) in order to improve TBU product yield.

According to embodiments of the invention, this TBU threshold current yield issue is addressed by trimming the TBU during fabrication to adjust the current threshold. Here “trimming” is understood to refer to adjusting parameters of one or more devices of a TBU during TBU fabrication. Such trimming is often performed in connection with device and/or TBU characterization, where measured values from the characterization are used as inputs for the trimming. Trimming as practiced in embodiments of the invention entails making one-time adjustments to device parameters during fabrication, as opposed to providing components having parameter values that can be changed multiple times and/or after fabrication is complete (e.g., a variable resistor, etc.).

In a first approach, a resistive circuit is added to the TBU in series with the pertinent transistor on-resistance. This additional resistive circuit has a resistance that can be adjusted during fabrication, to compensate for variations in transistor on-resistance and/or threshold voltage. In a second approach, a TBU transistor is fabricated as a segmented device having an on-resistance that depends on the number of transistor segments connected to terminals in final wire bonding.

Trimming as described above can also be employed to adjust the resistance of the TBU when it is in its normal current conducting state, since process variation of this TBU resistance can be a significant problem in some situations.

### BRIEF DESCRIPTION OF THE DRAWINGS

FIG. 1 shows a prior art uni-directional transient blocking unit.

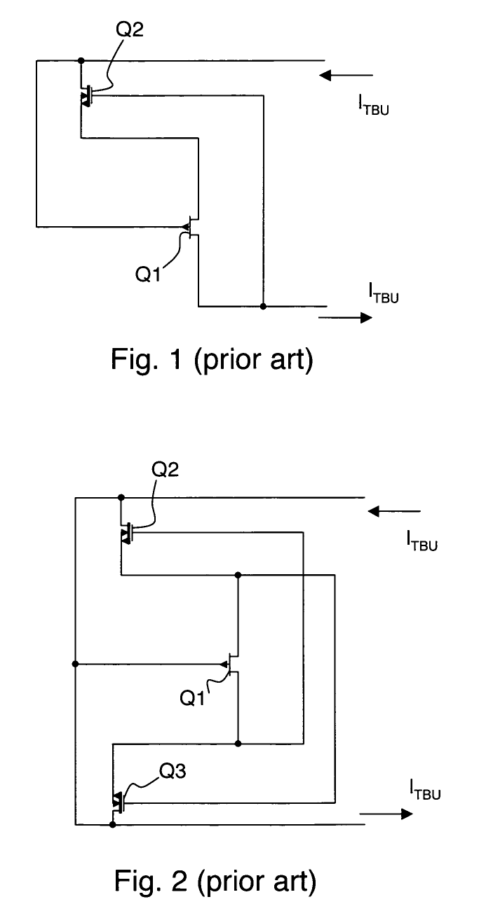

FIG. 2 shows a prior art bi-directional transient blocking unit.

FIG. 3 shows a uni-directional transient blocking unit in accordance with an embodiment of the invention.

FIG. 4 shows a bi-directional transient blocking unit in accordance with an embodiment of the invention.

FIG. 5 shows a bi-directional transient blocking unit in accordance with another embodiment of the invention.

FIGS. 6a-c show segmented transistors suitable for use in connection with embodiments of the invention.

### DETAILED DESCRIPTION

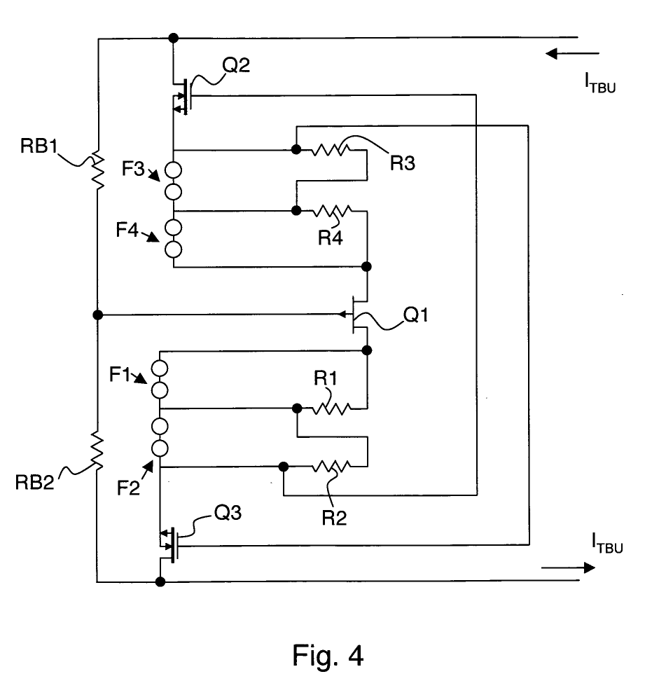

FIG. 3 shows a uni-directional transient blocking unit in accordance with an embodiment of the invention. In this example, a first depletion mode transistor Q1 and a second depletion mode transistor Q2 are connected in series with each other such that when I_{TBU} exceeds a first current threshold (T1), transistors Q1 and Q2 automatically switch to a high impedance blocking state. In this example, trimming of the TBU during fabrication to adjust T1 is provided by a resistive trimming circuit connected in series with Q1 and Q2, where a resistance of the resistive trimming circuit can be selected during fabrication.

More specifically, the resistive trimming circuit of FIG. 3 includes resistors R1 and R2 connected in series, each of the resistors also being connected in parallel to a corresponding fuse. Here fuses F1 and F2 correspond to resistors R1 and R2 respectively.

In this example, the resistance of the resistive circuit can be selected during fabrication according to whether or not F1 and F2 are set to an open or short state during fabrication, as indicated in the following table.

| F1 | F2 | resistance |
|---|---|---|
| open | open | R1 + R2 |
| open | short | R1 |
| short | open | R2 |
| short | short | 0 |

Preferably, R1 and R2 have different values (e.g., R1=1Ω and R2=2Ω), so that different resistance values are obtained when only R1 or only R2 is providing resistance. In this example, possible values for the resistive circuit resistances are 0, 1, 2, and 3 Ohms.

The resistance of the resistive trimming circuit is in series with the on-resistance of transistor Q1. Therefore, it contributes to the gate voltage of Q2 in the same way that the on-resistance of Q1 contributes. Accordingly, the resistance of the resistive trimming circuit can be selected during fabrication to compensate for transistor on-resistance and/or Vₜ variation, thereby improving the consistency of the TBU threshold current.

For example, suppose the transistor on-resistance (Rₒₙ) as fabricated varies over a range from 2 to 6 Ohms. A nominal total resistance R₀ can be selected (e.g., 5Ω), and the resistance Rₜ of the trimming circuit can be selected during fabrication (in response to measurements of Rₒₙ) such that R=Rₜ+Rₒₙ is as close as possible to the nominal total resistance R₀. In this example, the total resistance R would vary over a range from 5 to 6 Ohms, thereby providing a substantial improvement in threshold current consistency. Embodiments of the invention can include resistive trimming circuits having one or more resistors, each in parallel with its corresponding fuse.

In some cases, it is more important to provide an appropriate match of the on-resistance of Q1 to measured characteristics of Q2 than it is to make the effective on-resistance of Q1 more uniform. For example, suppose the TBU current threshold is given by a function f (Rₒₙ, Q2ₚₐᵣₘ), where Rₒₙ is the on-resistance of Q1, and Q2ₚₐᵣₘ are the relevant parameters of Q2 (e.g., threshold voltage), and suppose that the parameters of Q2 vary significantly from device to device. In practice, Q2 is typically an NMOS transistor, and the threshold voltage of an NMOS depletion mode transistor is a relatively poorly controlled device parameter. In this situation, it is preferred to select the trimming resistance Rₜ such that the current threshold f(Rₜ+Rₒₙ, Q2ₚₐᵣₘ) is as uniform as possible, based on measured values of Q2ₚₐᵣₘ. The flexibility in on-resistance provided by trimming can be exploited to provide either of these functions (i.e., making the effective Rₒₙ more uniform, or directly making the current threshold more uniform).

In the example of FIG. 3, current flowing through the TBU as indicated on the figure encounters Q2, then Q1, then the resistive trimming circuit. It is also possible for the resistive trimming circuit to be disposed between Q1 and Q2, such that current flowing through the TBU encounters Q2, the trimming circuit, and then Q1. In either case, the resistance provided by the resistive trimming circuit is in series with the pertinent transistor on-resistance (i.e., the on-resistance of Q1), so operation of the circuit is as described above. In other words, the resistive trimming circuit X is in series with Q1 and Q2, and the Q2-Q1-X and Q2-X-Q1 sequences are both applicable.

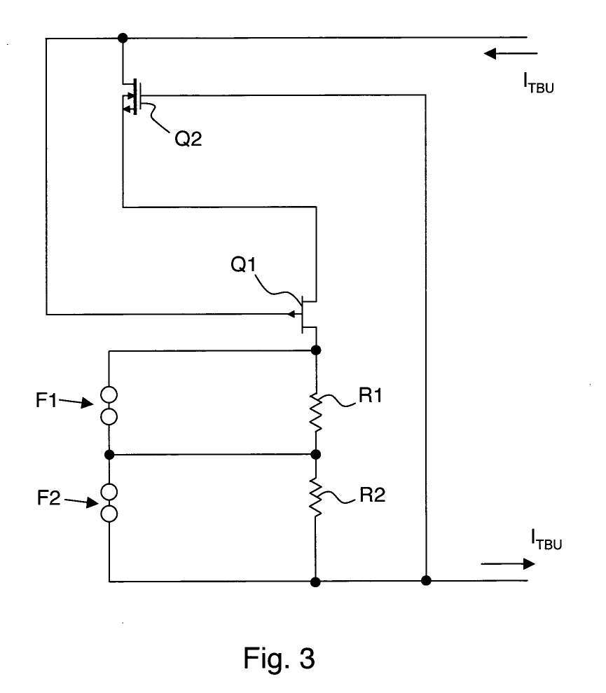

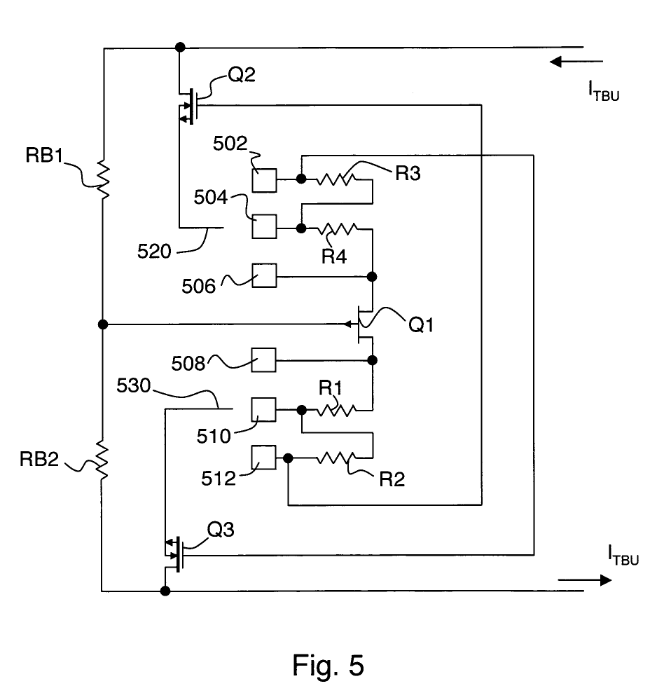

Trimming in accordance with principles of the invention is also applicable to bi-directional TBUs. FIG. 4 shows an example of such a bi-directional transient blocking unit. The circuit of FIG. 4 can be understood as a modified version of the bi-directional TBU of FIG. 2, where a resistive trimming circuit of the kind described in connection with FIG. 3 is added. The example of FIG. 4 also shows biasing elements RB1 and RB2, which can be resistors and/or diodes disposed to prevent substantial current flow to or from the gate of Q1. Such biasing elements are known in connection with TBUs, and therefore need no further description here.

In this example, a first depletion mode transistor Q1, a second depletion mode transistor Q2, and a third depletion mode transistor Q3 are connected in series with each other such that when I_{TBU} exceeds a first current threshold (T1), transistors Q1 and Q2 automatically switch to a high impedance blocking state, and such that when I_{TBU} exceeds a second current threshold (T2), transistors Q1 and Q3 automatically switch to a high impedance blocking state, where thresholds T1 and T2 have opposite polarity.

Thresholds T1 and T2 can be adjusted during fabrication by blowing none, some or all of fuses F1, F2, F3, and F4. For example, if R2=2R1, R3=4R1 and R4=8R1, then the resistive trimming circuit can provide any resistance selected from the set {0, R1, 2R1, 3R1, 4R1, 5R1, 6R1, 7R1, 8R1, 9R1, 10R1, 11R1, 12R1, 13R1, 14R1, 15R1} according to which fuses are open or short after fabrication is complete. The resistance provided by the resistive trimming circuit is in series with the on-resistance of Q1, and can therefore be set to compensate for variations in Q1 on-resistance as described above.

In some preferred embodiments of the invention, the resistive trimming circuit is made symmetric with respect to Q1 (e.g., R1=R4=1Ω, R2=R3=2Ω). Furthermore, in such embodiments, the resistance of the resistive trimming circuit is set during trimming to be disposed as symmetrically as possible relative to Q1. This configuration is preferred because it tends to reduce asymmetry in TBU characteristics. Having series resistances with different values on either side of Q1 in the circuit of FIG. 4 causes the circuit to start to turn off at different current values, depending on the polarity of I_{TBU}. Although this asymmetry has a relatively small effect on TBU threshold, because Q2 or Q3 tend to start switching off before Q1 as I_{TBU} increases, it is still often preferred to minimize this effect.

However, the option of trimming the resistance on both side of Q1 to different values may in some circumstances be useful. For example, it can be used to trim the turn-off characteristic of the TBU to ensure that for both current directions the TBU turns off at the same absolute current level in situations where transistors Q2 and Q3 are not exactly matched. This is another embodiment of the invention.

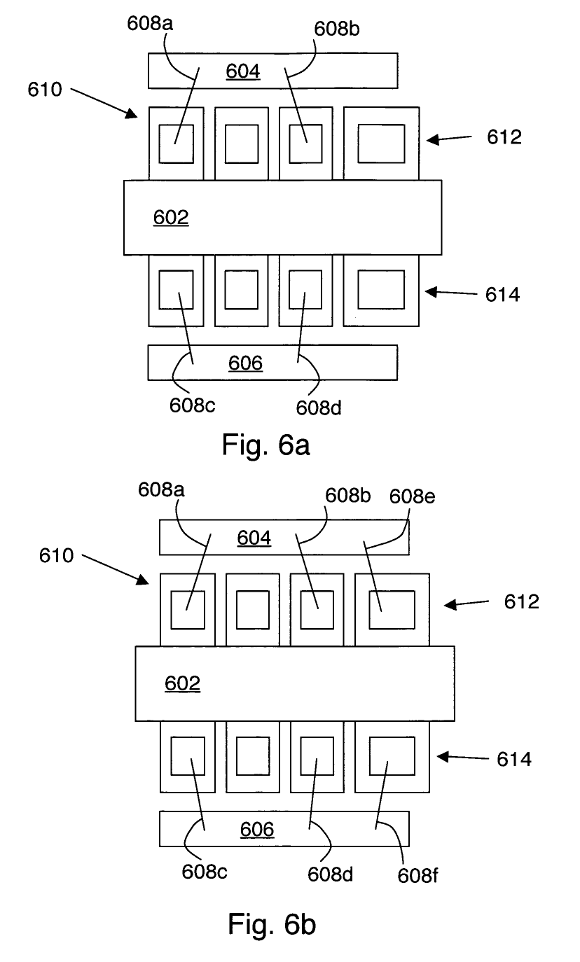

The preceding examples show resistive trimming circuits that include resistors and fuses. The invention can also be practiced with other kinds of resistive trimming circuits. For example, FIG. 5 shows a bi-directional transient blocking unit having a resistive trimming circuit that includes one or more resistors and wire bonding contact pads connected in alternating series.

More specifically, contact pads 502, 504 and 506 are connected in alternating series with resistors R3 and R4. Similarly, contact pads 508, 510, and 512 are connected in alternating series with resistors R1 and R2. The resistance of the resistive trimming circuit in this example is selected during fabrication by selecting which of contact pads 502, 504, and 506 is connected to lead 520, and by selecting which of contact pads 508, 510, and 512 is connected to lead 530. These connections of leads to pads can be made by conventional techniques, such as wire bonding.

The adjustability provided in this manner can be appreciated by example. Suppose resistance values are as follows: R1=R4=X, R2=R3=2X. Then the resistances that can obtained by the various bonding combinations are as given in the following table:

| Lead 520 connection | Lead 530 connection | Total R |
|---|---|---|
| 502 | 508 | 3X |
| 502 | 510 | 5X |
| 502 | 512 | 6X |
| 504 | 508 | X |
| 504 | 510 | 3X |
| 504 | 512 | 4X |
| 506 | 508 | 0 |
| 506 | 510 | 2X |
| 506 | 512 | 3X |

Here the total R value is the total resistance provided by the resistive trimming circuit in the main TBU current path (i.e., through transistors Q2, Q1, and Q3 in series). Even though R1, R2, R3, and R4 are always in the circuit in view of their connections to the gates of transistors Q2 and Q3, they are only relevant if the main TBU current flows through them. For example, when lead 520 is connected to pad 504 or to pad 506, there is no significant voltage drop across R3 because the gate current of transistor Q3 is negligible. Thus, R3 does not contribute to the on-resistance in this situation, as indicated in the preceding table. This example shows trimming circuits having two resistors and three pads in alternating sequence. This approach is applicable to one or more resistors in alternating series with two or more contact pads.

In this example, resistors R1, R2, R3, and R4 are low value resistors, which can conveniently be fabricated by patterning one of the metal layers of the transistor fabrication process. Other kinds of resistors are also applicable (e.g., polysilicon resistors). Assuming typical levels of process variation in a numerical example, the threshold current standard deviation can be reduced from 11.2% to 4.9% following the approach of FIG. 5. Further reduction of threshold current standard deviation can be obtained by providing more resistance options in the resistive trimming circuit (e.g., by increasing the number of resistors in series) and/or by choosing different resistance values in the trimming circuit.

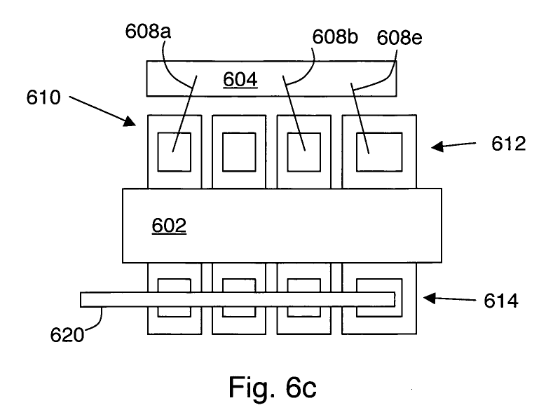

The preceding examples show trimming approaches based on providing a resistive trimming circuit suitable for making one-time adjustments of a resistance in series with the on-resistance of the relevant transistor (i.e., Q1 of the figures). Another approach is to fabricate Q1 such that its on-resistance can be altered during later stages of fabrication. For example, FIGS. 6a-b show a top view of a segmented transistor suitable for use in connection with an embodiment of the invention.

In this example, the transistor of FIG. 6a has a device-level source terminal 604 and a device-level drain terminal 606. It also includes two or more segments 610, each segment having a corresponding source and drain. The segment sources are referenced by 612, and the segment drains are referenced by 614. Thus each segment can be regarded as a source-drain pair. A common gate 602 controls current flow in each source drain pair. The segments can have the same width or different widths (the case of different widths is shown).

The on-resistance of the final device can be adjusted by selecting some or all of the source-drain pairs to be connected to the device level terminals 604 and 606. By adding more and/or larger segments in parallel, the on-resistance can be adjusted. For example, the configuration of FIG. 6a shows connection of two segments to the device terminals with bonds 608a-d, and the configuration of FIG. 6b shows connection of three segments to the device terminals with bonds 608a-f. This approach can be regarded as providing a transistor having a width that is adjustable at a late stage of fabrication. Such width adjustment is helpful for TBU fabrication, because on-resistance depends on transistor width. Individual characterization of the transistor segments may or may not be performed in the course of trimming the TBU, depending on how well controlled the parameters of individual segments are.

FIG. 6c shows an alternative segmented transistor approach that reduces the number of wire bonds required to select the transistor on-resistance. This example is similar to the example of FIG. 6b, except that all segment drains 614 are connected together by a device level drain terminal 620. Selective wire bonding of segment sources 612 to device level source terminal 604 can be employed to select the transistor on-resistance. In this case, as in the examples of FIGS. 6a-b, the resulting device has one or more segments connected in parallel to the device level source and drain terminals, thereby providing for adjustment of the on-resistance. In this example, the roles of source and drain can be reversed (i.e., all segment sources connected together, and segment drains selectively wire bonded).

One or more of the transistors of a TBU can be segmented transistors as on FIGS. 6a-b. In such cases, it is typically preferred for the center transistor of a bi-directional TBU to be segmented (e.g., Q1 on FIGS. 2, 4, and 5).

One aspect of the invention is a method for TBU fabrication including trimming the TBU during fabrication to adjust the TBU current threshold. Another aspect of the invention is a TBU circuit including means for trimming the TBU during fabrication to adjust the TBU current threshold. One kind of means for trimming described above, by example, is a resistive trimming circuit. Such a resistive trimming circuit can be any circuit that provides a resistance Rₜᵣᵢₘ in series with a pertinent transistor on-resistance, where the resistance Rₜᵣᵢₘ can be set to one of several values by a one-time adjustment during fabrication. For example, the resistors+fuses approach of FIGS. 3 and 4, and the selective bonding approach of FIG. 5, are both “means for trimming” in this sense.

Another means for trimming, also described above by example, is a TBU transistor having a fab-adjustable on-resistance. For example, the segmented transistor of FIGS. 6a-b has a fab-adjustable on-resistance. Other approaches for providing transistors having a fab-adjustable on-resistance are also applicable “means for trimming” for practicing the invention.

The preceding description has been by way of example as opposed to limitation, and so many details shown and/or described are not essential for practicing the invention. For example, bi-directional TBUs are shown having Q2 and Q3 being N-channel MOSFETs, and having Q1 being a P-channel JFET. This configuration is preferred, but not required, and embodiments of the invention can be practiced with any combination of transistor types that provides the basic TBU functionality as described above.

The preceding description has mainly focused on the situation where trimming of a TBU is performed to adjust the TBU threshold current (i.e., the current value at which it turns off). It is also possible to employ any or all of the trimming techniques or means for trimming described above in order to adjust the resistance provided by the TBU when it is in its normal conducting state. Hereinafter, this resistance is referred to as the “TBU resistance”.

1. A method of making a transient blocking unit (TBU) for protecting a series-connected load, the method comprising:
providing a first depletion mode transistor;
providing a second depletion mode transistor;
connecting said first and second depletion mode transistors in series with each other such that when a TBU current through said first and second transistors exceeds a first current threshold, said first and second transistors automatically switch to a high impedance blocking state; and
trimming said TBU during fabrication to adjust said first current threshold or to adjust a TBU resistance of said TBU.

2. The method of claim 1,
wherein at least one of said first and second depletion mode transistors is a multi-segment device having a plurality of source-drain pairs and having a device-level source terminal and a device-level drain terminal; and
wherein said trimming said TBU during fabrication comprises making electrical connections, in parallel, of one or more of said source-drain pairs to said device-level source and drain terminals, to select an on-resistance of said multi-segment device during fabrication.

3. The method of claim 1, wherein said trimming said TBU during fabrication comprises:
providing a resistive trimming circuit connected in series with said first depletion mode transistor and said second depletion mode transistor, and
selecting a resistance of said resistive trimming circuit during fabrication.

4. The method of claim 3, wherein said resistive trimming circuit comprises one or more resistors and two or more wire bonding contact pads connected in alternating series.

5. The method of claim 3, wherein said resistive trimming circuit comprises one or more resistors connected in series, each of said resistors being connected in parallel to a fuse.

6. The method of claim 1, wherein said first current threshold has a first polarity, and further comprising:
providing a third depletion mode transistor;
connecting said third depletion mode transistor in series with said first and second depletion mode transistors such that said TBU current can flow through said first, second, and third transistors, and such that when said TBU current exceeds a second current threshold having a second polarity opposite said first polarity, said first and third transistors automatically switch to a high impedance blocking state.

7. The method of claim 6, further comprising:
trimming said TBU during fabrication to adjust said second current threshold.

8. A transient blocking unit (TBU) for protecting a series-connected load, the TBU comprising:
a first depletion mode transistor;
a second depletion mode transistor, wherein said first and second depletion mode transistors are connected in series with each other such that when a TBU current through said first and second transistors exceeds a first current threshold, said first and second transistors automatically switch to a high impedance blocking state; and
means for trimming said TBU during fabrication to adjust said first current threshold or to adjust a TBU resistance of said TBU.

9. The transient blocking unit of claim 8,
wherein at least one of said first and second depletion mode transistors is a multi-segment device having a plurality of source-drain pairs and having a device-level source terminal and a device-level drain terminal; and
wherein said means for trimming comprises electrical connections, made in parallel, of one or more of said source-drain pairs to said device-level source and drain terminals, whereby an on-resistance of said multi-segment device can be selected during fabrication.

10. The transient blocking unit of claim 8,
wherein said means for trimming comprises a resistive trimming circuit connected in series with said first depletion mode transistor and said second depletion mode transistor, and
wherein a resistance of said resistive trimming circuit can be selected during fabrication.

11. The transient blocking unit of claim 10, wherein said resistive trimming circuit comprises one or more resistors and two or more wire bonding contact pads connected in alternating series.

12. The transient blocking unit of claim 10, wherein said resistive trimming circuit comprises one or more resistors connected in series, each of said resistors being connected in parallel to a fuse.

13. The transient blocking unit of claim 8, further comprising a third depletion mode transistor connected in series with said first and second depletion mode transistors, whereby said TBU current can flow through said first, second and third transistors,
wherein said first current threshold has a first polarity; and
wherein said third transistor is connected to said first transistor such that when said TBU current exceeds a second current threshold having a second polarity opposite said first polarity, said first and third transistors automatically switch to a high impedance blocking state.

14. The transient blocking unit of claim 13, further comprising: means for trimming said TBU during fabrication to adjust said second current threshold.
